(19) United States
(12) Patent Application Publication
(10) Pub. No.: US 2024/0141150 A1
(43) Pub. Date: May 2, 2024

(54) RESIN COMPOSITION, CURED PRODUCT, LAMINATE, TRANSPARENT ANTENNA, MANUFACTURING METHOD THEREFOR, AND IMAGE DISPLAY DEVICE

(71) Applicant: Resonac Corporation, Tokyo (JP)

(72) Inventors: Daisuke OTSUKI, Tokyo (JP); Masato MIYATAKE, Tokyo (JP); Shigeru KOIBUCHI, Tokyo (JP); Takeshi NOJIRI, Tokyo (JP)

(21) Appl. No.: 18/547,235

(22) PCT Filed: Feb. 21, 2022
(86) PCT No.: PCT/JP2022/006958

§ 371 Date: Aug. 21, 2023

(30) Foreign Application Priority Data
Feb. 22, 2021 (JP) 2021-026218

(51) Int. Cl. C08L 15/00; B32B 15/02; B32B 15/09; B32B 15/20; B32B 27/08; B32B 27/36; C08L 9/06; H01Q 1/38; H01Q 1/40

(52) U.S. Cl. CPC C08L 15/00; B32B 15/02; B32B 15/09; B32B 15/20; B32B 27/08; B32B 27/36; C08L 9/06; H01Q 1/38; H01Q 1/40; B32B 2255/10; B32B 2255/26; B32B 2307/202; B32B 2307/204; B32B 2307/412; B32B 2307/414; B32B 2307/54; B32B 2457/20

(57) ABSTRACT

A resin composition, containing: an elastomer; a (meth)acrylic compound; and a thermal polymerization initiator. A cured product of the resin composition. A laminate having: a base material film; and a transparent resin layer disposed on the base material film, in which the transparent resin layer contains the resin composition or the cured product. A transparent antenna 110, having: a transparent base material 110a; and a mesh-shaped conductive member 110b disposed on the transparent base material 110a, in which the transparent base material 110a contains the cured product. An image display device 100 has the transparent antenna 110.

### TECHNICAL FIELD

The present disclosure relates to a resin composition, a cured product, a laminate, a transparent antenna, a manufacturing method therefor, an image display device, and the like.

### BACKGROUND ART

An image display device is used in various electronic devices such as a personal computer, a car navigation, a mobile phone, a watch, and an electronic dictionary. The image display device has an image display unit displaying an image, and a bezel portion (a frame portion) positioned around the image display unit. In the image display unit, a transparent antenna connected to the bezel portion via a circuit is disposed. As a member for obtaining the transparent antenna, various members are considered (for example, refer to Patent Literature 1 described below).

### CITATION LIST

### Patent Literature

Patent Literature 1: Japanese Unexamined Patent Publication No. 2011-091788

### SUMMARY OF INVENTION

### Technical Problem

The transparent antenna has a transparent base material, and a conductive member disposed on the transparent base material, and there is a case where the transparent base material is formed of a cured product of a resin composition. Such a cured product is required to have a low degree of yellowness, from the viewpoint of attaining excellent color reproducibility in the image display device or the like.

An object of one aspect of the present disclosure is to provide a resin composition capable of obtaining a cured product with a low degree of yellowness. An object of another aspect of the present disclosure is to provide a cured product of the resin composition. An object of another aspect of the present disclosure is to provide a laminate using the resin composition or the cured product. An object of another aspect of the present disclosure is to provide a transparent antenna using the cured product. An object of another aspect of the present disclosure is to provide an image display device using the transparent antenna. An object of another aspect of the present disclosure is to provide a manufacturing method for a transparent antenna using the aforementioned laminate.

### Solution to Problem

One aspect of the present disclosure relates to a resin composition, containing: an elastomer; a (meth)acrylic compound; and a thermal polymerization initiator. According to such a resin composition, it is possible to obtain a cured product with a low degree of yellowness.

Another aspect of the present disclosure relates to a cured product of the aforementioned resin composition. Another aspect of the present disclosure relates to a laminate having: a base material film; and a transparent resin layer disposed on the base material film, in which the transparent resin layer contains the aforementioned resin composition or the aforementioned cured product. Another aspect of the present disclosure relates to a transparent antenna, having: a transparent base material; and a conductive member disposed on the transparent base material, in which the transparent base material contains the aforementioned cured product. Another aspect of the present disclosure relates to an image display device, having the aforementioned transparent antenna.

Another aspect of the present disclosure relates to a manufacturing method for a transparent antenna, including laminating the transparent resin layer of the aforementioned laminate on a transparent member. Another aspect of the present disclosure relates to a manufacturing method for a transparent antenna, in a case where the aforementioned laminate is a laminate in which the conductive member includes a first conductive member disposed on the transparent resin layer, and a second conductive member disposed on the first conductive member, and the first conductive member and the second conductive member contain copper, the method including removing the second conductive member in a state where the transparent resin layer and the conductive member of the laminate are laminated on a transparent member.

### Advantageous Effects of Invention

According to one aspect of the present disclosure, it is possible to provide the resin composition capable of obtaining the cured product with a low degree of yellowness. According to another aspect of the present disclosure, it is possible to provide the cured product of the resin composition. According to another aspect of the present disclosure, it is possible to provide the laminate using the resin composition or the cured product. According to another aspect of the present disclosure, it is possible to provide the transparent antenna using the cured product. According to another aspect of the present disclosure, it is possible to provide the image display device using the transparent antenna. According to another aspect of the present disclosure, it is possible to provide the manufacturing method for a transparent antenna using the aforementioned laminate.

### BRIEF DESCRIPTION OF DRAWINGS

FIG. 1 is a schematic sectional view illustrating an example of a laminate.

FIG. 2 is a schematic sectional view illustrating an example of the laminate.

FIG. 3 is a schematic sectional view illustrating an example of an image display device.

FIG. 4 is a schematic sectional view illustrating an example of the image display device.

### DESCRIPTION OF EMBODIMENTS

Hereinafter, an embodiment of the present disclosure will be described in detail. However, the present disclosure is not limited to the following embodiment.

In the present specification, “A or more” in a numerical range indicates A and a range more than A. “A or less” in a numerical range indicates A and a range less than A. In numerical ranges described in stages in the present specification, the upper limit value or the lower limit value of a numerical range in a certain stage may be arbitrarily combined with the upper limit value or the lower limit value of a numerical range in the other stage. In the numerical range described in the present specification, the upper limit value or the lower limit value of the numerical range may be replaced with values described in Examples. “A or B” may include either A or B, or may include both. Materials exemplified in the present specification can be used alone, or two or more types thereof can be used in combination, unless otherwise specified. In the present specification, in a case where there are a plurality of substances corresponding to each component in a composition, unless otherwise specified, the content of each component in the composition indicates the total amount of the plurality of substances in the composition. The terms “layer” and “film” include not only a structure in which a layer or a film is formed on the entire surface but also a structure in which a layer or a film is formed on a part of the surface when observed as a plan view. The term “step” includes not only an independent step but also a step that is not explicitly distinguishable from other steps insofar as a desired function of the step is attained. “(Meth)acrylate” indicates at least one of acrylate and methacrylate corresponding thereto. The same applies to other similar expressions such as “(meth)acryl”. The content of a (meth)acrylic compound indicates the total amount of an acrylic compound and a methacrylic compound.

A resin composition of the present embodiment contains an elastomer, a (meth)acrylic compound, and a thermal polymerization initiator. The resin composition of the present embodiment is a thermosetting resin composition. A cured product of the present embodiment is obtained by curing (thermally curing) the resin composition of the present embodiment, and is a cured product (a thermally cured product) of the resin composition of the present embodiment. For example, in the resin composition of the present embodiment, the cured product may be obtained by curing (thermally curing) the resin composition at 170° C. for 1 hour. The cured product of the present embodiment may be in a semi-cured state, or may be in a completely cured state.

According to the resin composition of the present embodiment, it is possible to obtain the cured product with a low degree of yellowness.

An image display device can be used in a high-frequency band communication device for attaining high-speed and high-capacity communication. In high-frequency band communication, there is a tendency that a transmission loss is large. Accordingly, a member configuring a transparent antenna is required to have excellent dielectric characteristics. According to one aspect of the resin composition of the present embodiment, it is possible to obtain the cured product having an excellent dielectric constant (a low dielectric constant). In addition, according to one aspect of the resin composition of the present embodiment, it is possible to obtain the cured product having an excellent dielectric dissipation factor (a low dielectric dissipation factor).

According to one aspect of the resin composition of the present embodiment, it is possible to obtain the cured product having an excellent transmittance. According to one aspect of the resin composition of the present embodiment, it is possible to obtain the cured product having an excellent haze. According to one aspect of the resin composition of the present embodiment, it is possible to obtain the cured product having an excellent degree of elongation. According to one aspect of the resin composition of the present embodiment, it is possible to obtain the cured product having an excellent elastic modulus (for example, a tensile elastic modulus) (a small elastic modulus).

The resin composition of the present embodiment contains the elastomer. Examples of the elastomer include a styrene-based elastomer, an olefin-based elastomer, a urethane-based elastomer, a polyester-based elastomer, a polyamide-based elastomer, and a silicone-based elastomer. The elastomer may include the styrene-based elastomer, from the viewpoint of easily obtaining the cured product with a low degree of yellowness and from the viewpoint of easily obtaining excellent dielectric characteristics (a dielectric constant, a dielectric dissipation factor, or the like) in the cured product.

The styrene-based elastomer has a styrene compound as a monomer unit, and may have a monomer unit derived from the styrene compound. Examples of the styrene compound include styrene; alkyl styrene such as methyl styrene, dimethyl styrene, trimethyl styrene, ethyl styrene, diethyl styrene, triethyl styrene, propyl styrene, butyl styrene, hexyl styrene, heptyl styrene, and octyl styrene; halogenated styrene such as fluorostyrene, chlorostyrene, bromostyrene, dibromostyrene, and iodostyrene; nitrostyrene; acetyl styrene; and methoxy styrene. The styrene-based elastomer may have styrene as a monomer unit, from the viewpoint of easily obtaining the cured product with a low degree of yellowness and from the viewpoint of easily obtaining excellent dielectric characteristics (a dielectric constant, a dielectric dissipation factor, or the like) in the cured product.

Examples of the styrene-based elastomer include a styrene-butadiene random copolymer, a styrene-butadiene-styrene block copolymer, a styrene-isoprene-styrene block copolymer, a styrene-ethylene-butylene-styrene block copolymer, a styrene-ethylene-propylene-styrene block copolymer, and a hydrogenated elastomer thereof.

The content of the styrene-based elastomer may be 50% by mass or more, 70% by mass or more, 90% by mass or more, 95% by mass or more, or 99% by mass or more, on the basis of the total mass of the elastomer (the total amount of the elastomer contained in the resin composition), from the viewpoint of easily obtaining the cured product with a low degree of yellowness and from the viewpoint of easily obtaining excellent dielectric characteristics (a dielectric constant, a dielectric dissipation factor, or the like) in the cured product. The elastomer contained in the resin composition may be an embodiment substantially composed of the styrene-based elastomer (an embodiment in which the content of the styrene-based elastomer is substantially 100% by mass, on the basis of the total mass of the elastomer contained in the resin composition).

The weight average molecular weight (Mw) or the number average molecular weight (Mn) of the elastomer may be in a range described below, from the viewpoint of easily obtaining the cured product with a low degree of yellowness and from the viewpoint of easily obtaining excellent dielectric characteristics (a dielectric constant, a dielectric dissipation factor, or the like) in the cured product. The weight average molecular weight or the number average molecular weight of the elastomer may be 1000 or more, 3000 or more, 4000 or more, 5000 or more, 10000 or more, 30000 or more, 50000 or more, 80000 or more, or 100000 or more. The weight average molecular weight or the number average molecular weight of the elastomer may be 500000 or less, 300000 or less, 200000 or less, 150000 or less, or 100000 or less. From these viewpoints, the weight average molecular weight or the number average molecular weight of the elastomer may be 1000 to 500000, 3000 to 300000, 4000 to 200000, or 5000 to 150000. The weight average molecular weight and the number average molecular weight (Mn) can be obtained by measuring with a gel permeation chromatography (GPC) method in the following condition, and converting with a standard polystyrene calibration curve.

Pump: L-6200 type [manufactured by Hitachi High-Technologies Co., Ltd.]

Detector: L-3300 type RI [manufactured by Hitachi High-Technologies Co., Ltd.]

Column Oven: L-655A-52 [manufactured by Hitachi High-Technologies Co., Ltd.]

Guard Column and Column: TSK Guardcolumn HHR-L+TSKgel G4000HHR+TSKgel G2000HHR [Product Names, all are manufactured by Tosoh Corporation]

Column Size: 6.0×40 mm (the guard column), 7.8×300 mm (the column)

Eluent: tetrahydrofuran

Sample Concentration: 30 mg/5 mL

Injection Amount: 20 μL

Flow Rate: 1.00 mL/minute

Measurement Temperature: 40° C.

The melt flow rate (MFR, 230° C., 5 kgf, Unit: g/10 minutes) of the elastomer measured on the basis of ISO 1133 may be in a range described below. MFR of the elastomer may be 1 or more, 2 or more, 3 or more, 4 or more, 5 or more, or 6 or more, from the viewpoint of easily obtaining the cured product with a low degree of yellowness and from the viewpoint of easily obtaining an excellent dielectric constant in the cured product. MFR of the elastomer may be 7 or more, from the viewpoint of easily obtaining an excellent haze and a more excellent dielectric constant in the cured product. MFR of the elastomer may be 10 or less, 9 or less, 8 or less, 7 or less, or 6 or less, from the viewpoint of easily obtaining the cured product with a low degree of yellowness and from the viewpoint of easily obtaining an excellent transmittance in the cured product. MFR of the elastomer may be 5 or less, from the viewpoint of easily obtaining an excellent haze and a more excellent transmittance in the cured product. From these viewpoints, MFR of the elastomer may be 1 to 10, 3 to 8, 5 to 7, 4 to 6, or 6 to 8.

The vicat softening temperature (a test load of 10 N, a temperature increase rate of 50° C./h) of the elastomer measured on the basis of ISO may be in a range described below. The vicat softening temperature of the elastomer may be 50° C. or higher, 60° C. or higher, 70° C. or higher, 72° C. or higher, 75° C. or higher, 80° C. or higher, 81° C. or higher, or 83° C. or higher, from the viewpoint of easily obtaining excellent haze, dielectric dissipation factor, and elongation in the cured product. The vicat softening temperature of the elastomer may be 100° C. or lower, 90° C. or lower, 85° C. or lower, or 83° C. or lower, from the viewpoint of easily obtaining the cured product with a low degree of yellowness. The vicat softening temperature of the elastomer may be 81° C. or lower, 80° C. or lower, 75° C. or lower, or 72° C. or lower, from the viewpoint of easily obtaining an excellent elongation in the cured product. From these viewpoints, the vicat softening temperature of the elastomer may be 50 to 100° C., 60 to 90° C., or 70 to 85° C.

The elastomer in the resin composition of the present embodiment may contain an elastomer component which provides a tensile elastic modulus (25° C.) in a range described below in a single film (a film composed of a target elastomer component). The tensile elastic modulus may be 1 MPa or more, 5 MPa or more, 10 MPa or more, 50 MPa or more, 100 MPa or more, 150 MPa or more, 200 MPa or more, 250 MPa or more, 300 MPa or more, 310 MPa or more, 320 MPa or more, 350 MPa or more, or 380 MPa or more, from the viewpoint of easily obtaining excellent haze and elastic modulus in the cured product. The tensile elastic modulus may be 500 MPa or less, 450 MPa or less, 400 MPa or less, 380 MPa or less, 350 MPa or less, 320 MPa or less, or 310 MPa or less, from the viewpoint of easily obtaining the cured product with a low degree of yellowness. From these viewpoints, the tensile elastic modulus may be 1 to 500 MPa, 100 to 400 MPa, 200 to 400 MPa, 300 to 400 MPa, 200 to 350 MPa, or 310 to 400 MPa.

The content of the elastomer may be in a range described below, on the basis of the total amount of the resin composition (excluding the mass of an organic solvent) or the total mass of the elastomer, the (meth)acrylic compound, and the thermal polymerization initiator, from the viewpoint of easily obtaining the cured product with a low degree of yellowness and from the viewpoint of easily obtaining excellent dielectric characteristics (a dielectric constant, a dielectric dissipation factor, or the like) in the cured product. The content of the elastomer may be 50% by mass or more, more than 50% by mass, 60% by mass or more, 65% by mass or more, 70% by mass or more, 75% by mass or more, or 78% by mass or more. The content of the elastomer may be 95% by mass or less, 90% by mass or less, 85% by mass or less, or 80% by mass or less. From these viewpoints, the content of the elastomer may be 50 to 95% by mass, 60 to 90% by mass, or 70 to 85% by mass.

The content of the elastomer may be in a range described below, on the basis of the total amount of the elastomer and the (meth)acrylic compound, from the viewpoint of easily obtaining the cured product with a low degree of yellowness and from the viewpoint of easily obtaining excellent dielectric characteristics (a dielectric constant, a dielectric dissipation factor, or the like) in the cured product. The content of the elastomer may be 50% by mass or more, more than 50% by mass, 60% by mass or more, 65% by mass or more, 70% by mass or more, 75% by mass or more, or 80% by mass or more. The content of the elastomer may be 95% by mass or less, 90% by mass or less, 85% by mass or less, or 80% by mass or less. From these viewpoints, the content of the elastomer may be 50 to 95% by mass, 60 to 90% by mass, or 70 to 85% by mass.

The resin composition of the present embodiment contains the (meth)acrylic compound. The (meth)acrylic compound is a compound having a (meth)acryloyl group. The (meth)acrylic compound may not have an epoxy group, or may have an epoxy group.

The (meth)acrylic compound may include at least one type selected from the group consisting of a monofunctional (meth)acrylic compound and a polyfunctional (meth)acrylic compound (a difunctional (meth)acrylic compound or a trifunctional or higher (meth)acrylic compound). For example, the “difunctional (meth)acrylic compound” indicates a compound in which the total number of an acryloyl group and a methacryloyl group in one molecule is 2. The (meth)acrylic compound may include the difunctional (meth)acrylic compound, from the viewpoint of easily obtaining the cured product with a low degree of yellowness.

Examples of the monofunctional (meth)acrylic compound include aliphatic (meth)acrylate such as methyl (meth)acrylate, ethyl (meth)acrylate, butyl (meth)acrylate, isobutyl (meth)acrylate, tert-butyl (meth)acrylate, butoxy ethyl (meth)acrylate, isoamyl (meth)acrylate, hexyl (meth)acrylate, 2-ethyl hexyl (meth)acrylate, heptyl (meth)acrylate, octyl heptyl (meth)acrylate, nonyl (meth)acrylate, decyl (meth)acrylate, undecyl (meth)acrylate, lauryl (meth)acrylate, tridecyl (meth)acrylate, tetradecyl (meth)acrylate, pentadecyl (meth)acrylate, hexadecyl (meth)acrylate, stearyl (meth)acrylate, behenyl (meth)acrylate, 2-hydroxyethyl (meth)acrylate, 2-hydroxypropyl (meth)acrylate, 3-chloro-2-hydroxypropyl (meth)acrylate, 2-hydroxybutyl (meth)acrylate, methoxy polyethylene glycol (meth)acrylate, ethoxy polyethylene glycol (meth)acrylate, methoxy polypropylene glycol (meth)acrylate, ethoxy polypropylene glycol (meth)acrylate, and mono(2-(meth)acryloyl oxyethyl) succinate; alicyclic (meth)acrylate such as cyclopentyl (meth)acrylate, cyclohexyl (meth)acrylate, cyclopentyl (meth)acrylate, dicyclopentanyl (meth)acrylate, dicyclopentenyl (meth)acrylate, isobornyl (meth)acrylate, mono(2-(meth)acryloyl oxyethyl) tetrahydrophthalate, and mono(2-(meth)acryloyl oxyethyl) hexahydrophthalate; aromatic (meth)acrylate such as benzyl (meth)acrylate, phenyl (meth)acrylate, o-biphenyl (meth)acrylate, 1-naphthyl (meth)acrylate, 2-naphthyl (meth)acrylate, phenoxy ethyl (meth)acrylate, p-cumyl phenoxy ethyl (meth)acrylate, o-phenyl phenoxy ethyl (meth)acrylate, 1-naphthoxy ethyl (meth)acrylate, 2-naphthoxy ethyl (meth)acrylate, phenoxy polyethylene glycol (meth)acrylate, nonyl phenoxy polyethylene glycol (meth)acrylate, phenoxy polypropylene glycol (meth)acrylate, 2-hydroxy-3-phenoxy propyl (meth)acrylate, 2-hydroxy-3-(o-phenyl phenoxy)propyl (meth)acrylate, 2-hydroxy-3-(1-naphthoxy)propyl (meth)acrylate, and 2-hydroxy-3-(2 -naphthoxy)propyl (meth)acrylate; heterocyclic (meth)acrylate such as 2-tetrahydrofurfuryl (meth)acrylate, N-(meth)acryloyl oxyethyl hexahydrophthalimide, and 2-(meth)acryloyl oxyethyl-N-carbazole; and modified caprolactone thereof.

Examples of the difunctional (meth)acrylic compound include aliphatic (meth)acrylate (for example, alkanediol di(meth)acrylate) such as ethylene glycol di(meth)acrylate, diethylene glycol di(meth)acrylate, triethylene glycol di(meth)acrylate, tetraethylene glycol di(meth)acrylate, polyethylene glycol di(meth)acrylate, propylene glycol di(meth)acrylate, dipropylene glycol di(meth)acrylate, tripropylene glycol di(meth)acrylate, tetrapropylene glycol di(meth)acrylate, polypropylene glycol di(meth)acrylate, ethoxylated polypropylene glycol di(meth)acrylate, 1,3-butanediol di(meth)acrylate, 1,4-butanediol di(meth)acrylate, neopentyl glycol di(meth)acrylate, 3-methyl-1,5-pentanediol di(meth)acrylate, 1,6-hexanediol di(meth)acrylate, 2-butyl-2-ethyl-1,3-propanediol di(meth)acrylate, nonanediol di(meth)acrylate (for example, 1,9-nonanediol di(meth)acrylate), decanediol di(meth)acrylate (for example, 1,10-decanediol di(meth)acrylate), dodecanediol di(meth)acrylate (for example, 1,12-decanediol di(meth)acrylate), glycerin di(meth)acrylate, and ethoxylated 2-methyl-1,3-propanediol di(meth)acrylate; alicyclic (meth)acrylate such as cyclohexane dimethanol di(meth)acrylate, ethoxylated cyclohexane dimethanol di(meth)acrylate, propoxylated cyclohexane dimethanol di(meth)acrylate, ethoxylated propoxylated cyclohexane dimethanol di(meth)acrylate, tricyclodecane dimethanol di(meth)acrylate, ethoxylated tricyclodecane dimethanol di(meth)acrylate, propoxylated tricyclodecane dimethanol di(meth)acrylate, ethoxylated propoxylated tricyclodecane dimethanol di(meth)acrylate, ethoxylated hydrogenated bisphenol A di(meth)acrylate, propoxylated hydrogenated bisphenol A di(meth)acrylate, ethoxylated propoxylated hydrogenated bisphenol A di(meth)acrylate, ethoxylated hydrogenated bisphenol F di(meth)acrylate, propoxylated hydrogenated bisphenol F di(meth)acrylate, and ethoxylated propoxylated hydrogenated bisphenol F di(meth)acrylate; aromatic (meth)acrylate such as ethoxylated bisphenol A di(meth)acrylate, propoxylated bisphenol A di(meth)acrylate, ethoxylated propoxylated bisphenol A di(meth)acrylate, ethoxylated bisphenol F di(meth)acrylate, propoxylated bisphenol F di(meth)acrylate, ethoxylated propoxylated bisphenol F di(meth)acrylate, ethoxylated bisphenol AF di(meth)acrylate, propoxylated bisphenol AF di(meth)acrylate, ethoxylated propoxylated bisphenol AF di(meth)acrylate, ethoxylated fluorine-type di(meth)acrylate, propoxylated fluorene-type di(meth)acrylate, and ethoxylated propoxylated fluorene-type di(meth)acrylate; heterocyclic (meth)acrylate such as ethoxylated isocyanuric acid di(meth)acrylate, propoxylated isocyanuric acid di(meth)acrylate, and ethoxylated propoxylated isocyanuric acid di(meth)acrylate; modified caprolactone thereof; aliphatic epoxy (meth)acrylate such as neopentyl glycol-type epoxy (meth)acrylate; alicyclic epoxy (meth)acrylate such as cyclohexane dimethanol-type epoxy (meth)acrylate, hydrogenated bisphenol A-type epoxy (meth)acrylate, and hydrogenated bisphenol F-type epoxy (meth)acrylate; and aromatic epoxy (meth)acrylate such as resorcinol-type epoxy (meth)acrylate, bisphenol A-type epoxy (meth)acrylate, bisphenol F-type epoxy (meth)acrylate, bisphenol AF -type epoxy (meth)acrylate, and fluorene-type epoxy (meth)acrylate.

Examples of the trifunctional or higher (meth)acrylic compound include aliphatic (meth)acrylate such as trimethylol propane tri(meth)acrylate, ethoxylated trimethylol propane tri(meth)acrylate, propoxylated trimethylol propane tri(meth)acrylate, ethoxylated propoxylated trimethylol propane tri(meth)acrylate, pentaerythritol tri(meth)acrylate, ethoxylated pentaerythritol tri(meth)acrylate, propoxylated pentaerythritol tri(meth)acrylate, ethoxylated propoxylated pentaerythritol tri(meth)acrylate, pentaerythritol tetra(meth)acrylate, ethoxylated pentaerythritol tetra(meth)acrylate, propoxylated pentaerythritol tetra(meth)acrylate, ethoxylated propoxylated pentaerythritol tetra(meth)acrylate, ditrimethylol propane tetra(meth)acrylate, and dipentaerythritol hexa(meth)acrylate; heterocyclic (meth)acrylate such as ethoxylated isocyanuric acid tri(meth)acrylate, propoxylated isocyanuric acid tri(meth)acrylate, and ethoxylated propoxylated isocyanuric acid tri(meth)acrylate; modified caprolactone thereof; and aromatic epoxy (meth)acrylate such as phenol novolac-type epoxy (meth)acrylate and cresol novolac-type epoxy (meth)acrylate.

The (meth)acrylic compound may include the aliphatic (meth)acrylate, from the viewpoint of easily obtaining the cured product with a low degree of yellowness. The (meth)acrylic compound may include the alkanediol di(meth)acrylate, from the viewpoint of easily obtaining the cured product with a low degree of yellowness. From the viewpoint of easily obtaining the cured product having an excellent elastic modulus, the (meth)acrylic compound may include at least one type selected from the group consisting of the nonanediol di(meth)acrylate, the decanediol di(meth)acrylate, the dodecanediol di(meth)acrylate, and the tricyclodecane dimethanol di(meth)acrylate, may include at least one type selected from the group consisting of the nonanediol di(meth)acrylate, the decanediol di(meth)acrylate, and the dodecanediol di(meth)acrylate, may include at least one type selected from the group consisting of the nonanediol di(meth)acrylate and the decanediol di(meth)acrylate, and may include the nonanediol di(meth)acrylate. The (meth)acrylic compound may include an acrylic compound, from the viewpoint of easily obtaining an excellent elongation in the cured product. The (meth)acrylic compound may include a methacrylic compound, from the viewpoint of easily obtaining the cured product with a low degree of yellowness and from the viewpoint of easily obtaining an excellent dielectric dissipation factor in the cured product.

The (meth)acrylic compound may include a compound represented by General Formula (I) described below, from the viewpoint of easily obtaining the cured product with a low degree of yellowness and from the viewpoint of easily obtaining an excellent elastic modulus.

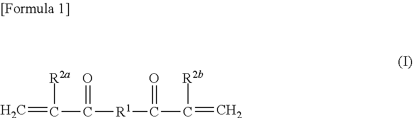

[In Formula (I), R′ represents a group having 9 or less carbon atoms and 2 or more oxygen atoms, and R^{2a} and R^{2b} each independently represent a hydrogen atom or a methyl group.]

The number of carbon atoms of R¹ is 1 to 9. The number of carbon atoms of R¹ may be 2 or more, 3 or more, 4 or more, 5 or more, 6 or more, 7 or more, or 8 or more, from the viewpoint of easily obtaining the cured product with a low degree of yellowness. The number of oxygen atoms of IV may be 6 or less, 5 or less, 4 or less, 3 or less, or 2 or less, from the viewpoint of easily obtaining the cured product with a low degree of yellowness. R¹ may be a hydrocarbon group in which oxygen atoms are bonded to both ends, and may be a “—O—CₙH₂ₙ—O—” group (n=1 to 9).

The content of the compound represented by General Formula (I) may be 50% by mass or more, 70% by mass or more, 90% by mass or more, 95% by mass or more, or 99% by mass or more, on the basis of the total mass of the (meth)acrylic compound (the total amount of the (meth)acrylic compound contained in the resin composition), from the viewpoint of easily obtaining the cured product with a low degree of yellowness. The (meth)acrylic compound contained in the resin composition may be an embodiment substantially composed of the compound represented by General Formula (I) (an embodiment in which the content of the compound represented by General Formula (I) is substantially 100% by mass, on the basis of the total mass of the (meth)acrylic compound contained in the resin composition).

The molecular weight of the (meth)acrylic compound may be in a range described below, from the viewpoint of easily obtaining the cured product with a low degree of yellowness. The molecular weight of the (meth)acrylic compound may be 80 or more, 100 or more, 120 or more, 150 or more, 180 or more, 200 or more, 220 or more, 250 or more, 260 or more, 280 or more, 290 or more, 300 or more, or 320 or more. The molecular weight of the (meth)acrylic compound may be 1000 or less, 800 or less, 600 or less, 550 or less, 500 or less, 450 or less, 400 or less, 350 or less, 320 or less, 300 or less, or 280 or less. From these viewpoints, the molecular weight of the (meth)acrylic compound may be 80 to 1000, 100 to 600, 100 to 500, 250 to 600, or 200 to 400.

The content of the (meth)acrylic compound may be in a range described below, on the basis of the total amount of the resin composition (excluding the mass of an organic solvent) or the total amount of the elastomer, the (meth)acrylic compound, and the thermal polymerization initiator, from the viewpoint of easily obtaining the cured product with a low degree of yellowness. The content of the (meth)acrylic compound may be 50% by mass or less, less than 50% by mass, 40% by mass or less, 35% by mass or less, 30% by mass or less, 25% by mass or less, or 20% by mass or less. The content of the (meth)acrylic compound may be 1% by mass or more, 5% by mass or more, 10% by mass or more, 15% by mass or more, or 18% by mass or more. From these viewpoints, the content of the (meth)acrylic compound may be 1 to 50% by mass, 10 to 40% by mass, or 15 to 25% by mass.

The content of the (meth)acrylic compound may be in a range described below, on the basis of the total amount of the elastomer and the (meth)acrylic compound, from the viewpoint of easily obtaining the cured product with a low degree of yellowness. The content of the (meth)acrylic compound may be 50% by mass or less, less than 50% by mass, 40% by mass or less, 35% by mass or less, 30% by mass or less, 25% by mass or less, or 20% by mass or less. The content of the (meth)acrylic compound may be 1% by mass or more, 5% by mass or more, 10% by mass or more, 15% by mass or more, or 20% by mass or more. From these viewpoints, the content of the (meth)acrylic compound may be 1 to 50% by mass, 10 to 40% by mass, or 15 to 25% by mass.

The resin composition of the present embodiment contains the thermal polymerization initiator. The thermal polymerization initiator is a compound for initiating polymerization by heating, may include a thermal radical polymerization initiator, and may include a thermal cationic polymerization initiator.

Examples of the thermal polymerization initiator include ketone peroxide such as methyl ethyl ketone peroxide, cyclohexanone peroxide, and methyl cyclohexanone peroxide; peroxyketal such as 1,1-bis(tert-butyl peroxy)cyclohexane, 1,1-bis(tert-butyl peroxy)-2-methyl cyclohexane, 1,1-bis(tert-butyl peroxy)-3,3,5-trimethyl cyclohexane, 1,1-bis(tert-hexyl peroxy)cyclohexane, and 1,1-bis(tert-hexyl peroxy)-3,3,5-trimethyl cyclohexane; hydroperoxide such as p-menthane hydroperoxide; dialkyl peroxide such as α,α′-bis(tert-butyl peroxy)diisopropyl benzene, dicumyl peroxide, tert-butyl cumyl peroxide, and di-tert-butyl peroxide; diacyl peroxide such as octanoyl peroxide, lauroyl peroxide, stearyl peroxide, and benzoyl peroxide; peroxycarbonate such as bis(4-tert-butyl cyclohexyl) peroxydicarbonate, di-2-ethoxy ethyl peroxydicarbonate, di-2-ethyl hexyl peroxydicarbonate, and di-3-methoxy butyl peroxycarbonate; peroxyester such as tert-butyl peroxypivalate, tert-hexyl peroxypivalate, 1,1,3,3-tetramethyl butyl peroxy-2-ethyl hexanoate, 2,5-dimethyl-2,5-bis(2-ethyl hexanoyl peroxy)hexane, tert-hexyl peroxy-2-ethyl hexanoate, tert-butyl peroxy-2-ethyl hexanoate, tert-butyl peroxyisobutyrate, tert-hexyl peroxyisopropyl monocarbonate, tert-butyl peroxy-3,5,5-trimethyl hexanoate, tert-butyl peroxylaurylate, tert-butyl peroxyisopropyl monocarbonate, tert-butyl peroxy-2-ethyl hexyl monocarbonate, tert-butyl peroxybenzoate, tert-hexyl peroxybenzoate, 2,5-dimethyl-2,5-bis(benzoyl peroxy)hexane, and tert-butyl peroxyacetate; an acid anhydride such as a phthalic anhydride, a maleic anhydride, a trimellitic anhydride, a hexahydrophthalic anhydride, a tetrahydrophthalic anhydride, a methyl nadic anhydride, a nadic anhydride, a glutaric anhydride, a dimethyl glutaric anhydride, a diethyl glutaric anhydride, a succinic anhydride, a methyl hexahydrophthalic anhydride, a methyl tetrahydrophthalic anhydride, a 1,2,3,4-cyclobutane tetracarboxylic dianhydride, a 4,4′-biphthalic anhydride, a 4,4′-carbonyl diphthalic anhydride, a 4,4′-sulfonyl diphthalic anhydride, a 4,4′-(hexafluoroisopropylidene) diphthalic anhydride, a 4,4′-oxydiphthalic anhydride, a 9,9-bis(3,4-dicarboxyphenyl) fluorene dianhydride, and a 2,3,6,7-naphthalene tetracarboxylic dianhydride; and an azo compound such as 2,2′-azobisisobutyronitrile, 2,2′-azobis(2,4-dimethyl valeronitrile), and 2,2′-azobis(4-methoxy-2′-dimethyl valeronitrile).

From the viewpoint of easily obtaining the cured product with a low degree of yellowness, the thermal polymerization initiator may include a peroxide, may include the dialkyl peroxide, and may include α,α′-bis(tert-butyl peroxy)diisopropyl benzene.

The content of the thermal polymerization initiator may be in a range described below, on the basis of the total mass of the resin composition (excluding the mass of an organic solvent) or the total amount of the elastomer, the (meth)acrylic compound, and the thermal polymerization initiator. The content of the thermal polymerization initiator may be 0.01% by mass or more, 0.03% by mass or more, 0.05% by mass or more, 0.08% by mass or more, or 0.09% by mass or more, from the viewpoint of easily obtaining the cured product with a low degree of yellowness and from the viewpoint of easily obtaining excellent curing properties. The content of the thermal polymerization initiator may be 10% by mass or less, 5% by mass or less, 1% by mass or less, 0.8% by mass or less, 0.5% by mass or less, 0.3% by mass or less, 0.2% by mass or less, or 0.1% by mass or less, from the viewpoint of easily obtaining the cured product with a low degree of yellowness. From these viewpoints, the content of the thermal polymerization initiator may be 0.01 to 10% by mass, 0.03 to 1% by mass, or 0.05 to 0.5% by mass.

The content of the thermal polymerization initiator may be in a range described below, on the basis of the total amount of the elastomer and the (meth)acrylic compound. The content of the thermal polymerization initiator may be 0.01% by mass or more, 0.03% by mass or more, 0.05% by mass or more, 0.08% by mass or more, or 0.1% by mass or more, from the viewpoint of easily obtaining the cured product with a low degree of yellowness and from the viewpoint of easily obtaining excellent curing properties. The content of the thermal polymerization initiator may be 10% by mass or less, 5% by mass or less, 1% by mass or less, 0.8% by mass or less, 0.5% by mass or less, 0.3% by mass or less, 0.2% by mass or less, or 0.1% by mass or less, from the viewpoint of easily obtaining the cured product with a low degree of yellowness. From these viewpoints, the content of the thermal polymerization initiator may be 0.01 to 10% by mass, 0.03 to 1% by mass, or 0.05 to 0.5% by mass.

The resin composition of the present embodiment may contain an additive other than the elastomer, the (meth)acrylic compound, and the thermal polymerization initiator. Examples of such an additive include a polymerizable compound (excluding a compound corresponding to the (meth)acrylic compound), a curing accelerator, an antioxidant, an ultraviolet ray absorber, a visible light absorber, a colorant, a plasticizer, a stabilizer, and a filler. Examples of the polymerizable compound include halogenated vinylidene, vinyl ether, vinyl ester, vinyl pyridine, vinyl amide, and arylated vinyl.

The resin composition of the present embodiment may contain an organic solvent. The resin composition of the present embodiment may be used as a resin varnish by diluting with the organic solvent. Examples of the organic solvent include aromatic hydrocarbon such as toluene, xylene, mesitylene, cumene, and p-cymene; cyclic ether such as tetrahydrofuran and 1,4-dioxane; ketone such as acetone, methyl ethyl ketone, methyl isobutyl ketone, cyclohexanone, and 4-hydroxy-4-methyl-2-pentanone; ester such as methyl acetate, ethyl acetate, butyl acetate, methyl lactate, ethyl lactate, and γ-butyrolactone; carbonate ester such as ethylene carbonate and propylene carbonate; and amide such as N,N-dimethyl formamide, N,N-dimethyl acetamide, and N-methyl pyrrolidone.

A laminate of the present embodiment has a base material film (a support film), and a transparent resin layer disposed on the base material film, in which the transparent resin layer contains the resin composition of the present embodiment or the cured product of the present embodiment.

Examples of the constituent material of the base material film include polyester (polyethylene terephthalate (PET), polybutylene terephthalate, polyethylene naphthalate, and the like), polyolefin (polyethylene, polypropylene, and the like), polycarbonate, polyamide, polyimide, polyamide imide, polyether imide, polyether sulfide, polyether sulfone, polyether ketone, polyphenylene ether, and polyphenylene sulfide. The thickness of the base material film may be 1 to 200 μm, 10 to 100 μm, or 20 to 50 μm.

The thickness of the transparent resin layer may be 1000 μm or less, 800 μm or less, 500 μm or less, 300 μm or less, 250 μm or less, 200 μm or less, 150 μm or less, or 100 μm or less, from the viewpoint of easily obtaining an excellent transmittance and from the viewpoint of easily thinning the image display device. The thickness of the transparent resin layer may be 1 μm or more, 5 μm or more, 10 μm or more, 20 μm or more, 30 μm or more, 50 μm or more, 80 μm or more, or 100 μm or more, from the viewpoint of easily reducing the transmission loss and from the viewpoint of easily improving antenna characteristics. From these viewpoints, the thickness of the transparent resin layer may be 1 to 1000 μm, 10 to 500 μm, 20 to 200 μm, or 50 to 200 μm.

A first aspect of the laminate of the present embodiment may have a protective film disposed on the transparent resin layer. A second aspect of the laminate of the present embodiment may have a conductive member disposed on the transparent resin layer.

As the constituent material of the protective film, the constituent material described above as the constituent material of the base material film can be used. The protective film may be the same film as the base material film, or may be a film different from the base material film. The thickness of the protective film may be 1 to 200 μm, 10 to 100 μm, or 20 to 50 μm.

The conductive member may be solid, or may have a pattern-shaped portion (may be patterned). In the conductive member having the pattern-shaped portion (hereinafter, referred to as a “pattern-shaped conductive member”), a part of the conductive member or the entire conductive member may be patterned. The pattern-shaped portion may be in the shape of a mesh, a spiral, or the like. In the case of using the transparent antenna having the solid conductive member, the conductive member may not be patterned (for example, may not be subjected to mesh processing). The pattern-shaped (for example, mesh-shaped) conductive member may be formed of a wire (for example, a metal wire). Examples of the constituent material of the conductive member include a metal material, a carbon material (for example, graphene), and a conductive polymer. Examples of the metal material include copper, silver, and gold. The conductive member may contain the copper, from the viewpoint of easily obtaining excellent conductivity and from the viewpoint of easily reducing a manufacturing cost.

The conductive member may be a single layer, or may be a plurality of layers. The conductive member of the plurality of layers may include, for example, a first conductive member (for example, a metal member) disposed on the transparent resin layer, and a second conductive member (for example, a metal member) disposed on the first conductive member. At least one type selected from the group consisting of the first conductive member and the second conductive member may be solid, or may be in the shape of a pattern (for example, in the shape of a mesh). The second conductive member can be used as a protective layer for suppressing the contamination, the damage, or the like of the first conductive member, and therefore, it is also possible to improve the handleability of the laminate. At least one type selected from the group consisting of the first conductive member and the second conductive member may contain copper, and the first conductive member and the second conductive member may contain copper.

The thickness of the conductive member (the total thickness in a case where the conductive member is a plurality of layers), the thickness of the first conductive member, or the thickness of the second conductive member may be in a range described below. The thickness may be 50 μm or less, 45 μm or less, 40 μm or less, 35 μm or less, 30 μm or less, 25 μm or less, 20 μm or less, 15 μm or less, 10 μm or less, 8 μm or less, 5 μm or less, 3 μm or less, 2 μm or less, or 1.5 μm or less, from the viewpoint of making the conductive member hard to chip and from the viewpoint of easily patterning the solid conductive member in a case where the solid conductive member is patterned (for example, is subjected to the mesh processing). The thickness may be 0.1 μm or more, 0.3 μm or more, 0.5 μm or more, 0.8 μm or more, 1 μm or more, or 1.2 μm or more, from the viewpoint of easily obtaining an excellent elongation. From these viewpoints, the thickness may be 0.1 to 50 μm, 0.1 to 30 μμm, 0.1 to 20 μm, 0.1 to 10 μm, 0.5 to 5 μm, or 1 to 3 μm.

The thickness of the first conductive member may be smaller than the thickness of the second conductive member. In a case where the conductive member is a plurality of layers, the thickness (the total thickness) of the conductive member or the thickness of the second conductive member may be 1.5 μm or more, 2 μm or more, 3 μm or more, 5 μm or more, 8 μm or more, 10 μm or more, 15 μm or more, or 20 μm or more.

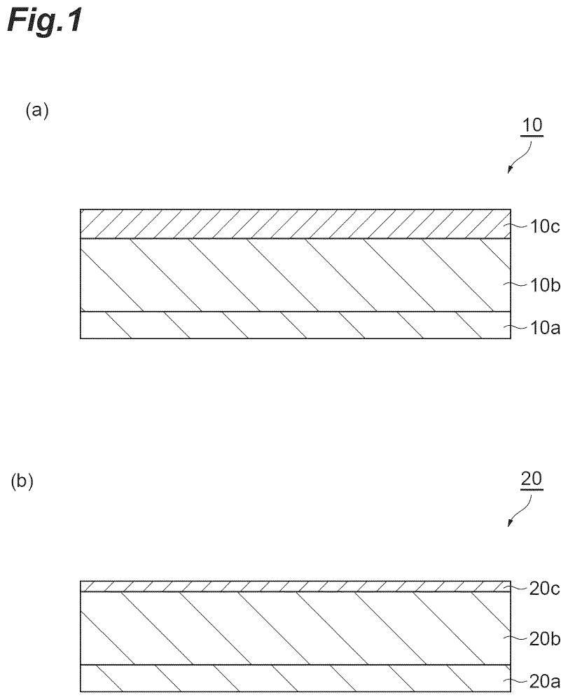

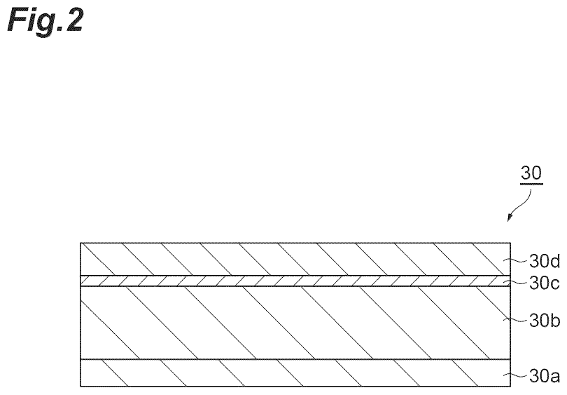

FIG. 1 and FIG. 2 are schematic sectional views illustrating an example of the laminate. A laminate 10 in FIG. 1(a) has a base material film 10a, a transparent resin layer 10b disposed on the base material film 10a, and a protective film 10c disposed on the transparent resin layer 10b. The transparent resin layer 10b is composed of the resin composition of the present embodiment or the cured product of the present embodiment. A laminate 20 in FIG. 1(b) has a base material film 20a, a transparent resin layer 20b disposed on the base material film 20a, and a conductive member 20c disposed on the transparent resin layer 20b. The transparent resin layer 20b is composed of the resin composition of the present embodiment or the cured product of the present embodiment. A laminate 30 in FIG. 2 has a base material film 30a, a transparent resin layer 30b disposed on the base material film 30a, a conductive member 30c disposed on the transparent resin layer 30b, and a conductive member 30d disposed on the conductive member 30c. The transparent resin layer 30b is composed of the resin composition of the present embodiment or the cured product of the present embodiment.

A transparent antenna of the present embodiment has a transparent base material, and a conductive member disposed on the transparent base material, in which the transparent base material contains the cured product of the present embodiment. The conductive member may be a single layer. As the configuration of the conductive member, the configuration described above regarding the conductive member of the laminate of the second aspect can be used. For example, the conductive member may contain copper. In addition, the conductive member may be solid, or may be in the shape of a pattern (for example, in the shape of a mesh). As the thickness of the transparent base material, the thickness described above regarding the transparent resin layer of the laminate of the present embodiment can be used.

The transparent antenna of the present embodiment may have a transparent member for supporting the transparent base material, that is, may have the transparent member, the transparent base material disposed on the transparent member, and the conductive member disposed on the transparent base material.

The shape of the transparent member is not particularly limited, and may be a film shape (a transparent film), a substrate shape (a transparent substrate), an irregular shape, or the like. Examples of the constituent material of the transparent member include a resin material and an inorganic material. Examples of the resin material include polyester (polyethylene terephthalate (PET), polybutylene terephthalate, polyethylene naphthalate, and the like), polyolefin (polyethylene, polypropylene, a cycloolefin polymer, and the like), polycarbonate, polyamide, polyimide, polyamide imide, polyether imide, polyether sulfide, polyether sulfone, polyether ketone, polyphenylene ether, and polyphenylene sulfide. Examples of the inorganic material include glass. The transparent member may be formed of a material with the total light transmittance of 90% or more. The transparent member may contain the polyolefin, from the viewpoint of low dielectric.

A first aspect of a manufacturing method for a transparent antenna of the present embodiment includes a processing step of patterning the conductive member (the solid conductive member) (for example, processing the conductive member into the shape of a mesh) disposed on the transparent base material containing the cured product of the present embodiment. In the processing step, the pattern-shaped (for example, mesh-shaped) conductive member may be obtained by etching the conductive member in a state where a pattern-shaped resist layer is disposed on the conductive member of the laminate having the transparent base material, and the conductive member disposed on the transparent base material. The resist layer may be removed after the conductive member is etched. The pattern-shaped resist layer can be obtained by irradiating (exposing) a photosensitive layer disposed on the conductive member with an active ray (for example, an ultraviolet ray), and then, by removing (developing) the unexposed portion or the exposed portion of the resist layer.

The laminate having the conductive member disposed on the transparent base material may be obtained by forming the conductive member on the transparent base material containing the cured product of the present embodiment, and for example, may be obtained by forming the conductive member on the transparent resin layer after the protective film of the laminate of the first aspect is removed. The laminate having the conductive member disposed on the transparent base material may be the laminate of the second aspect.

A second aspect of the manufacturing method for a transparent antenna of the present embodiment includes a forming step of forming a pattern-shaped (for example, mesh-shaped) metal member in a state where a pattern-shaped resist layer is disposed on the transparent base material containing the cured product of the present embodiment. In the forming step, the pattern-shaped (for example, mesh-shaped) metal member may be formed by plating or sputtering using the resist layer as a mask. The resist layer may be removed after the forming step.

A third aspect of the manufacturing method for a transparent

antenna of the present embodiment includes a removing step of removing the base material film of the laminate in a case where the conductive member of the laminate of the second aspect is in the shape of a pattern (for example, in the shape of a mesh). In a case where the transparent resin layer of the laminate in the removing step contains the cured product, the laminate of the transparent base material (the transparent resin layer) and the pattern-shaped (for example, mesh-shaped) conductive member can be obtained as the transparent antenna by the removing step. In a case where the transparent resin layer of the laminate in the removing step is uncured, the laminate of the transparent base material (the transparent resin layer) and the pattern-shaped (for example, mesh-shaped) conductive member can be obtained as the transparent antenna by curing the transparent resin layer (the resin composition of the transparent resin layer) after the removing step.

A fourth aspect of the manufacturing method for a transparent antenna of the present embodiment includes a laminating step of laminating the transparent resin layer of the laminate of the present embodiment on the transparent member. As the transparent member, the transparent member described above regarding the transparent antenna can be used. In the laminating step, the transparent resin layer may be laminated on the transparent member in a state where the base material film of the laminate of the present embodiment is removed, and the transparent resin layer may be laminated on the transparent member in a state where the protective film of the laminate of the first aspect is removed. The manufacturing method for a transparent antenna of the fourth aspect may include a removing step A of removing the base material film of the laminate of the present embodiment, and may include a removing step B of removing the protective film of the laminate of the first aspect.

In the case of using the laminate of the second aspect, in the laminating step, the transparent resin layer and the conductive member may be laminated on the transparent member in a state where the transparent resin layer is positioned closer to the side of the transparent member than the conductive member, and the transparent resin layer and the conductive member may be laminated on the transparent member in a state where the transparent resin layer is in contact with the transparent member. In the laminating step, the transparent resin layer and the conductive member can be laminated on the transparent member in a state where the base material film of the laminate of the second aspect is removed.

Incidentally, in a laminate having a transparent member, and a conductive member laminated on the transparent member, in the case of laminating the transparent member and the conductive member with excellent adhesiveness, there is a case where the transparent member is subjected to a surface treatment (a plasma treatment, a corona treatment, or the like), and the manufacturing procedure of the laminate can be complicated. For example, in the case of using polyolefin as the constituent material of the transparent member, since adhesiveness between the polyolefin and the conductive member (for example, a metal material such as copper) is low, there is a case where the surface treatment is required to be performed in order to obtain sufficient adhesiveness. On the other hand, according to the manufacturing method for a transparent antenna of the fourth aspect, it is possible to obtain the laminate of the transparent member and the conductive member (the laminate having the transparent member, the transparent resin layer, and the conductive member) as the transparent antenna while obtaining sufficient adhesiveness between the transparent member and the conductive member without requiring the surface treatment of the transparent member, and for example, it is possible to obtain the transparent antenna while obtaining sufficient adhesiveness between the transparent member containing polyolefin and the conductive member containing copper. In addition, according to the manufacturing method for a transparent antenna of the fourth aspect, it is possible to collectively supply the transparent resin layer and the conductive member onto the transparent member by laminating the laminate of the present embodiment on the transparent member, and it is possible to obtain the transparent antenna by a simple method. Further, according to the manufacturing method for a transparent antenna of the fourth aspect, it is possible to obtain the transparent antenna with excellent antenna characteristics by using a material with excellent dielectric characteristics (a permittivity, a dielectric dissipation factor, or the like) as the constituent material of the transparent resin layer.

In the manufacturing method for a transparent antenna of the fourth aspect, the transparent resin layer in the removing step A, the removing step B, and the laminating step may be uncured, or may be the cured product. In a case where the transparent resin layer is uncured, the manufacturing method for a transparent antenna of the fourth aspect may include a curing step of curing the transparent resin layer (the resin composition of the transparent resin layer) after the laminating step.

In the manufacturing method for a transparent antenna of the fourth aspect, the conductive member in the removing step A, the removing step B, and the laminating step may be solid, or may be in the shape of a pattern (for example, in the shape of a mesh). In a case where the conductive member is solid, the manufacturing method for a transparent antenna of the fourth aspect may include the processing step of patterning the conductive member (for example, processing the conductive member into the shape of a mesh) after the laminating step.

In the manufacturing method for a transparent antenna of the fourth aspect, the conductive member in the removing step A, the removing step B, and the laminating step may be a plurality of layers, and may include the first conductive member disposed on the transparent resin layer, and the second conductive member disposed on the first conductive member. At least one type selected from the group consisting of the first conductive member and the second conductive member may be solid, or may be in the shape of a pattern (for example, in the shape of a mesh). At least one type selected from the group consisting of the first conductive member and the second conductive member may contain copper, and the first conductive member and the second conductive member may contain copper. In a case where the conductive member includes the first conductive member and the second conductive member, in the laminating step, the transparent resin layer and the conductive member may be laminated on the transparent member in a state where the first conductive member is positioned closer to the side of the transparent member than the second conductive member. The manufacturing method for a transparent antenna of the fourth aspect may include a removing step C of removing the second conductive member after the laminating step. In the removing step C, the second conductive member can be peeled off from the first conductive member. The manufacturing method for a transparent antenna of the fourth aspect may include the processing step of patterning the first conductive member (for example, processing the first conductive member into the shape of a mesh) after the removing step C. In the processing step, for example, the first conductive member may be etched in a state where a pattern-shaped resist layer is disposed on the first conductive member. In a case where the transparent resin layer is uncured, the manufacturing method for a transparent antenna of the fourth aspect may include the curing step of curing the transparent resin layer (the resin composition of the transparent resin layer) before the removing step C, after the removing step C, or before and after the removing step C.

A fifth aspect of the manufacturing method for a transparent antenna of the present embodiment is a manufacturing method for a transparent antenna, using the laminate having the aforementioned base material film, the aforementioned transparent resin layer, and the aforementioned conductive member including the first conductive member and the second conductive member, in which the method includes the removing step C of removing the second conductive member in a state where the transparent resin layer and the conductive member are laminated on the transparent member while the transparent resin layer of the laminate is positioned closer to the side of the transparent member than the conductive member.

The manufacturing method for a transparent antenna of the fifth aspect may include the curing step of curing the transparent resin layer (the resin composition of the transparent resin layer) in a state where the transparent resin layer and the conductive member are laminated on the transparent member, before the second conductive member is removed, after the second conductive member is removed, or before and after the second conductive member is removed. In the curing step, the transparent resin layer may be cured in a state where the transparent resin layer and the conductive member are laminated on the transparent member while the transparent resin layer is positioned closer to the side of the transparent member than the conductive member. The manufacturing method for a transparent antenna of the fifth aspect may include the processing step of patterning the first conductive member (for example, processing the first conductive member into the shape of a mesh) after the second conductive member is removed (after the removing step C). An example of the manufacturing method for a transparent antenna of the fifth aspect is a manufacturing method using the laminate having the aforementioned base material film, the aforementioned transparent resin layer (the uncured transparent resin layer), the aforementioned conductive member including the first conductive member and the second conductive member, in which the method includes the aforementioned removing step A (a first removing step), laminating step, curing step, and removing step C (a second removing step). In the manufacturing method for a transparent antenna of the fifth aspect, at least one type selected from the group consisting of the first conductive member and the second conductive member may contain copper, and the first conductive member and the second conductive member may contain copper. In addition, the first conductive member of the laminate may be solid, or may be in the shape of a pattern (for example, in the shape of a mesh).

In the aforementioned manufacturing methods for a transparent antenna of the first to fifth aspects, the steps, the configurations, and the like described above regarding each of the aspects may be combined with each other. For example, in the manufacturing method for a transparent antenna of the fifth aspect, the steps, the configurations, and the like described above regarding the manufacturing method for a transparent antenna of the fourth aspect can be used.

An image display device of the present embodiment has the transparent antenna of the present embodiment. The image display device may have an image display unit displaying an image, and a bezel portion (a frame portion) positioned around the image display unit, and the transparent antenna may be disposed in the image display unit. The image display device may be used in various electronic devices such as a personal computer, a car navigation, a mobile phone, a watch, and an electronic dictionary.

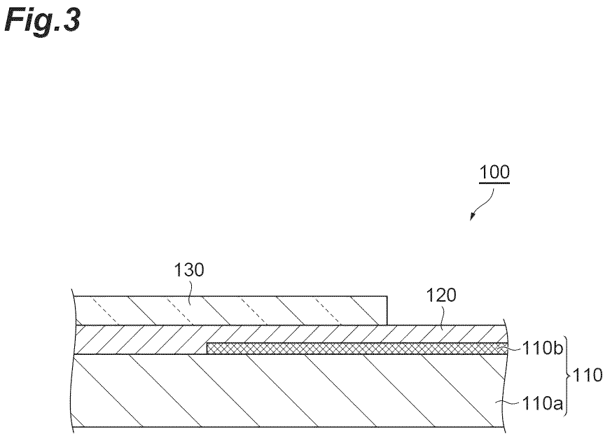

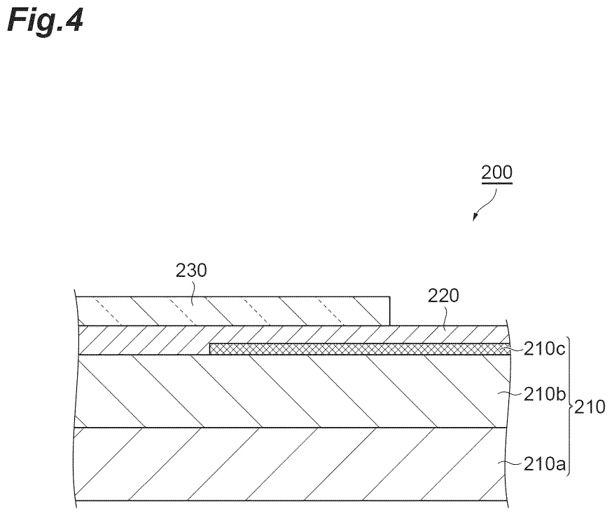

FIG. 3 and FIG. 4 are schematic sectional views illustrating an example of the image display device, and illustrate the image display unit of the image display device. An image display device 100 in FIG. 3 has a transparent antenna 110, a protective layer 120 disposed on the transparent antenna 110, and a transparent covering member 130 disposed on the protective layer 120. The transparent antenna 110 has a transparent base material 110a, and a mesh-shaped conductive member 110b disposed on the transparent base material 110a. An image display device 200 in FIG. 4 has a transparent antenna 210, a protective layer 220 disposed on the transparent antenna 210, and a transparent covering member 230 disposed on the protective layer 220. The transparent antenna 210 has a transparent member 210a, a transparent base material 210b disposed on the transparent member 210a, and a mesh-shaped conductive member 210c disposed on the transparent base material 210b. The transparent base materials 110a and 210b are composed of the cured product of the present embodiment. The conductive members 110b and 210c are formed of copper. The transparent member 210a is formed of polyolefin. The protective layers 120 and 220 cover the transparent base materials 110a and 210b and the conductive members 110b and 210c. The protective layers 120 and 220 may be formed of the resin composition or the cured product of the present embodiment, and may be formed of a material with the total light transmittance of 90% or more. The covering members 130 and 230 may be a glass plate.

### EXAMPLES

Hereinafter, the present disclosure will be further described by using Examples and Comparative Examples, but the present disclosure is not limited to the following Examples.

### Preparation of Resin Varnish

### Example 1

80 parts by mass of an elastomer 1 (a styrene-based elastomer, hydrogenated styrene butadiene rubber, Product Name: DYNARON 2324P, manufactured by JSR Corporation, Weight Average Molecular Weight: 1.0×10⁵), 20 parts by mass of an acrylic compound 1 (an acrylic monomer, 1,9-nonanediol diacrylate, Product Name: FA-129AS, manufactured by Showa Denko Materials Co., Ltd., a molecular weight of 268), 0.1 parts by mass of a thermal polymerization initiator (a thermal radical polymerization initiator, α,α′-bis(tert-butyl peroxy)diisopropyl benzene, Product Name: PERBUTYL P, manufactured by NOF CORPORATION), and 125 parts by mass of a solvent (toluene) were mixed while being stirred to obtain a resin varnish.

The elastic modulus (the tensile elastic modulus) of a single film of the elastomer 1 (a film composed of the elastomer 1) was measured in the following procedure. First, a toluene solution (Solid Content Concentration: 40% by mass) of the elastomer 1 was prepared, and then, this toluene solution was applied onto the release treated surface of a surface release treated PET film (Product Name: Purex A31, manufactured by Teijin Dupont Film Japan Limited, Thickness: 38 μm) by using a knife coater (Product Name: SNC-300, manufactured by Yasui Seiki Company., Ltd.). Next, drying was performed at 100° C. for 20 minutes in a dryer (Product Name: MSO-80TPS, manufactured by FUTABA Co., Ltd.), and then, a single film (Length: 50 mm, Width: 10 mm, Thickness: 100 μm) was obtained by removing the PET film. A stress-strain curve of the single film was measured by using an autograph (Product Name: EZ-S, manufactured by SHIMADZU CORPORATION) in the environment of 25° C. to obtain the elastic modulus from the stress-strain curve. A distance between chucks in the measurement was set to 20 mm, and a tensile rate was set to 50 mm/min. As the elastic modulus, a value at a load of 0.5 N to 1.0 N was measured. The elastic modulus of the single film of the elastomer 1 was 10 MPa. The elastic modulus of the following single films was measured in the same procedure as that of the single film of the elastomer 1.

### Examples 2 to 5

Resin varnishes were obtained as with Example 1, except that elastomers 2 to 5 (a styrene-based elastomer, styrene butadiene rubber) shown in Table 1 were used instead of the elastomer 1.

Elastomer 2: Product Name: “Ricon 100”, manufactured by Cray Valley, a number average molecular weight of 4500

Elastomer 3: Product Name: “Asaflex 810”, by ASAHI KASEI CORPORATION, MFR (ISO 1133, 200° C., 5 kgf) of 5 g/10 minutes, a vicat softening temperature (ISO 306, 10 N, 50° C./h) of 83° C., the elastic modulus of the single film of 314 MPa

Elastomer 4: Product Name: “Asaflex 830”, manufactured by Asahi Kasei Corp., MFR (ISO 1133, 200° C., 5 kgf) of 6 g/10 minutes, a vicat softening temperature (ISO 306, 10 N, 50° C./h) of 72° C., the elastic modulus of the single film of 301 MPa

Elastomer 5: Product Name: “Asaflex 840”, manufactured by Asahi Kasei Corp., MFR (ISO 1133, 200° C., 5 kgf) of 7 g/10 minutes, a vicat softening temperature (ISO 306, 10 N, 50° C./h) of 81° C., the elastic modulus of the single film of 387 MPa

### Examples 6 to 11

Resin varnishes were obtained as with Example 1, except that acrylic compounds 2 and 3 or methacrylic compounds 1 to 4 shown in Table 1 were used instead of the acrylic compound 1.

Acrylic Compound 2: 1,10-decanediol diacrylate, Product Name: “1,10-Bis(acryloyl oxy)decane”, manufactured by Tokyo Chemical Industry Co., Ltd.

Acrylic Compound 3: tricyclodecane dimethanol diacrylate, Product Name: “A-DCP”, manufactured by SHIN-NAKAMURA CHEMICAL Co., Ltd.

Methacrylic Compound 1: 1,9-nonanediol dimethacrylate, Product Name: “NOD-N”, manufactured by SHIN-NAKAMURA CHEMICAL Co., Ltd.

Methacrylic Compound 2: 1,10-decanediol dimethacrylate, Product Name: “DOD-N”, manufactured by SHIN-NAKAMURA CHEMICAL Co., Ltd.

Methacrylic Compound 3: 1,12-dodecanediol dimethacrylate, Product Name: “1,12-Dodecanediol Dimethacrylate”, manufactured by Tokyo Chemical Industry Co., Ltd.

Methacrylic Compound 4: tricyclodecane dimethanol dimethacrylate, Product Name: “DCP”, manufactured by SHIN-NAKAMURA CHEMICAL Co., Ltd.

### Comparative Example 1

A resin varnish was obtained as with Example 1, except that 1.5 parts by mass of a photopolymerization initiator (a photo-radical generator, bis(2,4,6-trimethyl benzoyl) phenyl phosphine oxide, Product Name: Irgacure 819, manufactured by BASF) was used instead of 0.1 parts by mass of the thermal polymerization initiator, and the amount of solvent was adjusted such that the total amount of the resin varnish was the same as that in Example 1.

### Production of Film for Evaluation

A surface release treated PET film (Product Name: Purex A31, manufactured by Teijin Dupont Film Japan Limited, Thickness: 38 μm) was prepared as a base material film. The aforementioned resin varnish was applied onto the release treated surface of this PET film by using a knife coater (Product Name: SNC-300, manufactured by Yasui Seiki Company, Ltd.). Next, drying was performed at 100° C. for 20 minutes in a dryer (Product Name: MSO-80TPS, manufactured by FUTABA Co., Ltd.) to form a resin film. By adjusting the gap of the coater, the thickness of the resin film after drying was adjusted to 100 μm. The same surface release treated PET film as the base material film was prepared as a protective film, and then, the release treated surface of the protective film was pasted to the resin film to obtain a laminating film.

The laminating films having the resin films obtained by using the resin varnishes of Examples 1 to 11 were subjected to a thermal treatment at 170° C. for 1 hour in a dryer (Product Name: MSO-80TPS, manufactured by FUTABA Co., Ltd.) to thermally cure the resin films, and therefore, films for evaluation having the cured films were obtained.

A laminating film having the resin film obtained by using the resin varnish of Comparative Example 1 was irradiated with an ultraviolet ray (a wavelength of 365 nm) at 2000 mJ/cm² using an ultraviolet ray exposure machine (Product Name: ML-320F SAT, manufactured by Mikasa Co., Ltd.) to photo-cure the resin film, and therefore, a film for evaluation having the cured film was obtained.

### Characteristic Evaluation

### (Y1, Total Light Transmittance, and Haze)

A laminate with a length of 30 mm and a width of 30 mm was cut out from the aforementioned film for evaluation, and then, the base material film and the protective film of this laminate were removed to obtain a test piece. The yellow index (YI), the total light transmittance, and the haze of the test piece were measured by using a spectroscopic hazemeter (Product Name: SH7000, manufactured by NIPPON DENSHOKU INDUSTRIES CO., LTD.) in the environment of 25° C. Results are shown in Table 1.

### Dielectric Constant and Dielectric Dissipation Factor

A laminate with a length of 80 mm and a width of 80 mm was cut out from the aforementioned film for evaluation as a test piece, and then, the dielectric constant and the dielectric dissipation factor of this entire test piece were measured with a split-post dielectric resonator technique (a SPDR method) by using a vector type network analyzer (Product Name: E8364B, manufactured by Agilent Technologies Japan, Ltd.) and a 10 GHz resonator (Product Name: CP531, manufactured by Kanto Electronics Application Development Co., Ltd.) in the environment of 25° C. In addition, a laminate (Length: 80 mm, Width: 80 mm) in which only the aforementioned base material film and the aforementioned protective film were laminated was produced, and then, the dielectric constant and the dielectric dissipation factor of this laminate were measured with the same method. By subtracting the measurement result of the aforementioned laminate from the measurement result of the aforementioned test piece, the dielectric constant and the dielectric dissipation factor of the cured film were obtained. Results are shown in Table 1.

### Degree of Elongation and Elastic Modulus

A laminate with a length of 40 mm and a width of 10 mm was cut out from the aforementioned film for evaluation, and then, the base material film and the protective film of this laminate were removed to obtain a test piece. A stress-strain curve of the test piece was measured by using an autograph (Product Name: EZ-S, manufactured by SHIMADZU CORPORATION) in the environment of 25° C. to obtain the degree of elongation and the elastic modulus (the tensile elastic modulus) from the stress-strain curve. A distance between chucks in the measurement was set to 20 mm, and a tensile rate was set to 50 mm/min. As the degree of elongation, the degree of breaking elongation when the test piece was broken was measured. As the elastic modulus, a value at a load of 0.5 N to 1.0 N was measured. Results are shown in Table 1.

TABLE 1

| | | | Example | | | | | |
|---|---|---|---|---|---|---|---|---|
| | | Unit | 1 | 2 | 3 | 4 | 5 | 6 |
| Composition | Elastomer 1 | Parts by | 80 | | | | | 80 |
| | Elastomer 2 | mass | | 80 | | | | |
| | Elastomer 3 | | | | 80 | | | |
| | Elastomer 4 | | | | | 80 | | |
| | Elastomer 5 | | | | | | 80 | |
| | Acrylic compound 1 | | 20 | 20 | 20 | 20 | 20 | |
| | Acrylic compound 2 | | | | | | | 20 |
| | Acrylic compound 3 | | | | | | | |
| | Methacrylic compound 1 | | | | | | | |
| | Methacrylic compound 2 | | | | | | | |
| | Methacrylic compound 3 | | | | | | | |
| | Methacrylic compound 4 | | | | | | | |
| | Thermal polymerization | | 0.1 | 0.1 | 0.1 | 0.1 | 0.1 | 0.1 |
| | initiator | | | | | | | |
| | Photopolymerization | | | | | | | |
| | initiator | | | | | | | |
| Characteristic | YI | — | 0.55 | 0.40 | 0.54 | 0.52 | 0.61 | 0.51 |
| evaluation | Total light transmittance | % | 92.12 | 90.98 | 90.50 | 90.38 | 90.33 | 92.08 |
| | Haze | % | 1.37 | 1.82 | 1.49 | 1.57 | 1.49 | 1.81 |
| | Dielectric constant | — | 2.23 | 2.25 | 2.26 | 2.24 | 2.23 | 2.22 |
| | Dielectric dissipation | — | 0.0038 | 0.0040 | 0.0038 | 0.0039 | 0.0039 | 0.0040 |
| | factor | | | | | | | |
| | Degree of elongation | % | 899 | 7 | 86 | 48 | 71 | 785 |
| | Elastic modulus | MPa | 0.8 | 182.1 | 226.1 | 245.6 | 201.3 | 0.9 |

| | | | | | | | Comparative |
|---|---|---|---|---|---|---|---|
| | | Example | | | | | Example |
| | | 7 | 8 | 9 | 10 | 11 | 1 |
| Composition | Elastomer 1 | 80 | 80 | 80 | 80 | 80 | 80 |
| | Elastomer 2 | | | | | | |
| | Elastomer 3 | | | | | | |
| | Elastomer 4 | | | | | | |
| | Elastomer 5 | | | | | | |
| | Acrylic compound 1 | | | | | | 20 |
| | Acrylic compound 2 | | | | | | |
| | Acrylic compound 3 | 20 | | | | | |
| | Methacrylic compound 1 | | 20 | | | | |
| | Methacrylic compound 2 | | | 20 | | | |
| | Methacrylic compound 3 | | | | 20 | | |
| | Methacrylic compound 4 | | | | | 20 | |
| | Thermal polymerization | 0.1 | 0.1 | 0.1 | 0.1 | 0.1 | |
| | initiator | | | | | | |
| | Photopolymerization | | | | | | 1.5 |
| | initiator | | | | | | |
| Characteristic | YI | 0.55 | 0.43 | 0.45 | 0.43 | 0.37 | 0.75 |
| evaluation | Total light transmittance | 92.01 | 92.09 | 92.08 | 92.11 | 92.18 | 92.02 |
| | Haze | 1.73 | 1.46 | 1.70 | 1.90 | 1.48 | 1.76 |
| | Dielectric constant | 2.22 | 2.19 | 2.32 | 2.21 | 2.31 | 2.20 |
| | Dielectric dissipation | 0.0043 | 0.0023 | 0.0024 | 0.0041 | 0.0031 | 0.0035 |
| | factor | | | | | | |
| | Degree of elongation | 888 | 686 | 534 | 554 | 667 | 800 |
| | Elastic modulus | 7.4 | 0.9 | 0.8 | 1.3 | 0.6 | 1.7 |

### REFERENCE SIGNS LIST

10, 20, 30: laminate, 10a, 20a, 30a: base material film, 10b, 20b, 30b: transparent resin layer, 10c: protective film, 20c, 30c, 30d, 110b, 210c: conductive member, 100, 200: image display device, 110, 210: transparent antenna, 110a, 210b: transparent base material, 120, 220: protective layer, 130, 230: covering member, 210a: transparent member.

1. A resin composition, comprising:
an elastomer;
a (meth)acrylic compound; and
a thermal polymerization initiator.

2. The resin composition according to claim 1,
wherein the (meth)acrylic compound includes alkanediol di(meth)acrylate.

3. The resin composition according to claim 1,
wherein the (meth)acrylic compound includes a compound represented by General Formula (I) described below. 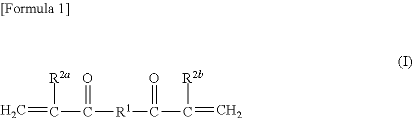
[In Formula (I), R¹ represents a group having 9 or less carbon atoms and 2 or more oxygen atoms, and R^{2a} and R^{2b} each independently represent a hydrogen atom or a methyl group.]

4. The resin composition according to claim 1,
wherein the thermal polymerization initiator includes a peroxide.

5. The resin composition according to claim 1,
wherein the thermal polymerization initiator includes dialkyl peroxide.

6. The resin composition according to claim 1,
wherein the elastomer includes a styrene-based elastomer.

7. A cured product of the resin composition according to claim 1.

8. A laminate comprising:
a base material film; and
a transparent resin layer disposed on the base material film,
wherein the transparent resin layer contains the resin composition according to claim 1 or the cured product of the resin composition.

9. The laminate according to claim 8, further comprising
a conductive member disposed on the transparent resin layer.

10. The laminate according to claim 9,
wherein the conductive member contains copper.

11. The laminate according to claim 9,
wherein a thickness of the conductive member is 2 μm or less.

12. The laminate according to claim 9,
wherein the conductive member includes a first conductive member disposed on the transparent resin layer, and a second conductive member disposed on the first conductive member, and
the first conductive member and the second conductive member contain copper.

13. A transparent antenna, comprising:
a transparent base material; and
a conductive member disposed on the transparent base material,
wherein the transparent base material contains the cured product according to claim 7.

14. The transparent antenna according to claim 13,
wherein the conductive member is in the shape of a mesh.

15. The transparent antenna according to claim 13,
wherein the conductive member contains copper.

16. An image display device, comprising
the transparent antenna according to claim 13.

17. A manufacturing method for a transparent antenna, comprising:
laminating the transparent resin layer of the laminate according to claim 8 on a transparent member.

18. A manufacturing method for a transparent antenna, comprising:
removing the second conductive member in a state where the transparent resin layer and the conductive member are laminated on the transparent member while the transparent resin layer of the laminate according to claim 12 is positioned closer to a side of the transparent member than the conductive member.

19. The manufacturing method for a transparent antenna according to claim 18,
wherein before the second conductive member is removed, the transparent resin layer is cured in a state where the transparent resin layer and the conductive member are laminated on the transparent member.

20. The manufacturing method for a transparent antenna according to claim 18,
wherein after the second conductive member is removed, the first conductive member is processed into the shape of a mesh.
